(19) United States
(12) Patent Application Publication
(10) Pub. No.: US 2007/0285978 A1
(43) Pub. Date: Dec. 13, 2007

(54) Magnetic memory and method of spin injection

(75) Inventor: Takashi Asatani, Tokyo (JP)

Correspondence Address: OLIFF & BERRIDGE, PLC, P.O. BOX 19928, ALEXANDRIA, VA, 22320, US

(73) Assignee: TDK CORPORATION, TOKYO (JP)

(21) Appl. No.: 11/727,507

(22) Filed: Mar. 27, 2007

(30) Foreign Application Priority Data
Mar. 30, 2006 (JP) P2006-094038

(51) Int. Cl. G11C 11/15

(52) U.S. Cl. 365/173

(57) ABSTRACT

According to this spin injection method, since a spin transfer torque assisted by an external magnetic field acts, a magnetization direction can be changed with a small current, and since the magnetization direction of a magnetosensitive layer can be controlled by just reducing the external magnetic field strength in the magnetosensitive layer, the external magnetic field carrying out an initial assist, a precise current control is not required and therefore the magnetization direction of the magnetosensitive layer can be changed by flowing a small current by simple control.

### BACKGROUND OF THE INVENTION

1. Field of the Invention

The present invention relates to a magnetic memory and a spin injection method.

2. Related Background of the Invention

MRAM (Magnetic Random Access Memory) has a structure in which a TMR (TMR; Tunnel Magnetoresistance) element is disposed at an intersection of a bit line and a word line that are wired in a grid-like manner. The TMR element includes a three-layer structure of ferromagnetic layer/non-magnetic insulating layer/ferromagnetic layer, having the non-magnetic layer between two ferromagnetic layers. The ferromagnetic layer is usually made of a transition-metal magnetic element (Fe, Co, Ni) with the thickness of 10 nm or less, or an alloy of the transition-metal magnetic elements (CoFe, CoFeNi, NiFe, or the like), and the non-magnetic insulating layer is made of Al₂O₃, MgO, or the like.

A magnetization direction of one ferromagnetic layer (fixed layer) that constitutes the TMR element is fixed, and a magnetization direction of the other ferromagnetic layer (magnetosensitive layer or free layer) rotates in response to an external magnetic field. Incidentally, as the structure of the fixed layer, an exchange coupling type of applying an antiferromagnetic layer (FeMn, IrMn, PtMn, NiMn, or the like) to one ferromagnetic layer is often used.

“1” and “0” of memory information are defined according to the state of the magnetization directions of two ferromagnetic materials that constitute the TMR element, i.e., depending on whether the magnetization directions are in parallel or antiparallel. When the magnetization directions of these two ferromagnetic materials are in antiparallel, the value of electric resistance in the thickness direction is high as compared with when the magnetization directions are in parallel.

Accordingly, the reading of information of “1” and “0” is carried out by flowing a current in the thickness direction of the TMR element and measuring the resistance value or current value of the TMR element due to MR (magnetic resistance) effect.

For the writing of information of “1” and “0”, conventionally, the magnetization direction of the magnetosensitive layer of the TMR element is rotated by the action of a magnetic field formed by flowing a current to a wiring disposed in the vicinity of the TMR element, thereby carrying out writing.

Moreover, for the write operation to convert the magnetizing direction of the magnetosensitive layer so as to correspond to “1” and “0” of information, a spin injection magnetization reversal using a spin transfer torque due to a spin polarization current is known other than a magnetization reversal method of applying a magnetic field to the magnetic material. As the method of reading information, a method is common in which a read selection transistor is provided in each cell and only the read transistor of the select cell is put in a conducting condition and then the resistance of magnetoresistance effect element of the select cell is read.

The spin transfer torque is a torque which, when a current is flowed from one ferromagnetic material to the other ferromagnetic material via a non-magnetic layer, attempts to convert the magnetization direction of the other ferromagnetic material. Accordingly, if the spin direction of an injection current is controlled, the magnetization direction of the other magnetic material may be changed.

The known methods of converting the magnetization direction of a ferromagnetic material using the spin transfer torque include: (I) a relaxing switching method; (II) a precessional switching method; and (III) a relaxing-precessional switching method.

In the relaxing switching method, the magnetization direction of a magnetosensitive layer is controlled by the spin transfer torque from a fixed layer, however, the magnetization direction of the fixed layer is in the film plane and is in parallel with a magnetization easy axis of the magnetosensitive layer. Accordingly, when reversing the magnetization direction of the magnetosensitive layer, in the initial stage of the reversal, the spin transfer torque conflicts with the spin relaxing that attempts to direct the magnetization toward the effective magnetic field direction. Moreover, in the initial stage of the reversal in which the magnetization direction of the fixed layer is almost in parallel with the magnetization direction of the magnetosensitive layer, the spin transfer torque is small and thus it takes time to reverse. That is, in the relaxing switching method, the magnetization direction is gradually changed to an equilibrium state while resisting these forces, and therefore, a large current is required for reversing the magnetization direction. The magnitude of the spin transfer torque required for the magnetization reversal is proportional to Gilbert attenuation coefficient that is included in LLG (Landau-Lifshitz-Gilbert) equation.

In the precessional switching method, the magnetization direction of the magnetosensitive layer is controlled by a spin transfer torque from the fixed layer, however, the magnetization direction of the fixed layer is perpendicular to the film plane and is perpendicular to the magnetization easy axis of the magnetosensitive layer. Due to the spin transfer torque, the magnetization direction of the magnetosensitive layer has a vertical component with respect to the film plane, and due to the demagnetizing field thereof it starts to rotate in the in-film plane direction. Since the spin transfer torque is constant even if the magnetization of the magnetosensitive layer rotates in the plane, the magnetization reversal is possible in a short time. However, since the spin transfer torque acts as long as a current is flowing after the magnetization reversal of the magnetosensitive layer, the magnetization of the magnetosensitive layer may be reversed again depending on the energizing time of the current. Accordingly, this method requires a very precise time control of the current.

Then, a devised relaxing-precessional switching method applies an external magnetic field to the magnetization difficult axis direction of the magnetosensitive layer in the precessional switching method. In this case, although the precise time control of the current required in the precessional switching method is not required, a precise control of the spin transfer torque is required.

Such magnetic memory is described in non-patent document 1 “Highly scalable MRAM using filed assisted current induced switching”, Symposium on VLSI Technology Digest of Technical Papers, p. 184-185, 2005, W. C. Jeong, J. H. Park, J. H. Oh, G. T. Jeong, H. S. Jeong and Kinam Kim, and in non-patent document 2 “Digests 29th Ann. Conf, Magnetics Society of Japan”, P 183, 2005, Hiroshi Morise and Shiho Nakamura, for example.

### SUMMARY OF THE INVENTION

As described above, in the conventional magnetic memories a large write current or a precise spin transfer torque is required, and therefore, in order to put these to practical use there are areas for improvement, such as a decrease in the product yield.

The present invention has been made in view of such problem and is intended to provide a magnetic memory and spin injection method that can change the magnetization direction of a magnetosensitive layer by flowing a small current by simple control.

In order to solve the above-described problem, the spin injection method concerning the present invention is a spin injection method of injecting electrons for changing a magnetization direction of a magnetosensitive layer, the method comprising: a first step of generating in a plane of the magnetosensitive layer an external magnetic field having a direction component perpendicular to a magnetization easy axis of the magnetosensitive layer; a second step of injecting in the magnetosensitive layer electrons having a spin polarized in a direction having a component perpendicular to a film plane; and a third step of reducing a magnetic field strength generated in the first step during execution of the second step.

In the first step, the magnetization direction of the magnetosensitive layer rotates toward a direction (direction of the magnetization difficult axis) perpendicular to the magnetization easy axis with the assist of an external magnetic field. Here, in the second step, if a polarized spin is injected in the magnetosensitive layer, a spin transfer torque also acts on a vector that defines the magnetization direction and the vector will rotate in the polarization direction of the polarized spin. As a result, the magnetization of the magnetosensitive layer has an out-of-plane direction component, and therefore, the magnetization of the magnetosensitive layer will rotate in parallel with the plane due to the magnetic anisotropy while attempting to direct the magnetization in the film plane. If continuously applying an external magnetic field to the magnetosensitive layer while applying a spin transfer torque, the vector with the magnetization direction of the magnetosensitive layer will precess, and therefore, in the third step, the magnetic field strength generated in the first step is reduced during the execution period of the second step, preferably reduced to zero, so that the magnetization direction of the magnetosensitive layer converges to the magnetization direction.

According to this spin injection method, since the spin transfer torque assisted by the external magnetic field acts, the magnetization direction can be changed with a small current, and since the magnetization direction can be controlled by just reducing the magnetic field strength generated in the first step so as to suppress an aberrance of magnetization direction due to precession, a precise current control is not required, and thus the magnetization direction of the magnetosensitive layer can be changed by flowing a small current by simple control.

The overlap time between the spin injection and the external magnetic field application is set to 75±10% of the ferromagnetic resonance, the external magnetic field is reversed, or the spin injection current is reversed.

Moreover, the overlap period between the execution period of the first step and the execution period of the second step is preferably 25±10% of the ferromagnetic resonance period of the magnetosensitive layer. Note that ±10% is an error. Namely, there is an advantage that in the case where the overlap period is approximately ¼ of the ferromagnetic resonance period, at this instant the magnetization easy axis direction component is the largest, thus ensuring the writing. The overlap period is preferably 25 to 62.5 pico seconds. In the case where the overlap period is approximately ¼ of the ferromagnetic resonance period T, the deflection angle from the magnetization difficult axis becomes the maximum, thus providing an advantage that erroneous write is unlikely to occur.

Moreover, the rising time period of the external magnetic field in the first step is preferably 25±10% of the ferromagnetic resonance period of the magnetosensitive layer. Note that +10% is an error. That is, in the case where the rising time period is approximately ¼ of the ferromagnetic resonance period, because an instant occurs that the magnetization direction of the magnetosensitive layer during precession agrees with the magnetization difficult axis, if the external magnetic field is strengthened so that the rising of the external magnetic field may complete at this time, then the magnetization direction will stay along the magnetization difficult axis.

In addition, this rising time period is preferably 40 to 60 pico seconds. This is because the ferromagnetic resonance period of the magnetosensitive layer during which the spin transfer torque acts effectively is approximately 100 to 250 pico seconds.

Moreover, the external magnetic field is preferably generated by flowing a current into an assist wiring that is provided in the vicinity of the magnetosensitive layer. That is, the external magnetic field can be generated in this manner.

A magnetic memory that performs the above-described function is a magnetic memory including a plurality of storage areas, the individual storage area includes: a fixed layer made of ferromagnetic material; a magnetosensitive layer having a magnetization easy axis along an in-plane direction, the magnetosensitive layer facing the fixed layer via a non-magnetic layer; an assist wiring for providing a magnetic field reversal assist magnetic field in the magnetosensitive layer; and a spin injection wiring connected to the fixed layer, and the magnetic memory further comprises: a first switch that turns on so as to supply a magnetic field reversal assist current to the assist wiring and to thus generate in the plane of the magnetosensitive layer an external magnetic field having a direction component perpendicular to a magnetization easy axis of the magnetosensitive layer; and a second switch that turns on so as to supply electrons to the spin injection wiring after turning on the first switch, wherein the first switch is turned off while the second switch is ON, and wherein a magnetization direction of the fixed layer is perpendicular to a film plane.

The polarized spin is generated by a spin filter having a fixed layer of ferromagnetic material and a non-magnetic layer, and this polarized spin is injected in the magnetosensitive layer. In the magnetosensitive layer, a magnetic field reversal assist magnetic field can be generated by means of the assist wiring, and the polarized spin can be injected via the spin injection wiring and spin filter.

Turning on the first switch, the first step of the spin injection method is carried out, and turning on the second switch, the second step is carried out and the first switch is turned off while the second switch is ON so that the third step may be carried out.

Thus, according to this magnetic memory, since the spin transfer torque acts on the magnetosensitive layer while being assisted by the external magnetic field like in the spin injection method described above, the magnetization direction can be changed with a small current and the magnetization direction can be controlled by just reducing the magnetic field strength generated in the first step so as to suppress an aberrance of magnetization direction due to precession, and therefore, the precise control of current value is not required and thus the magnetization direction of the magnetosensitive layer can be changed by flowing a small current by simple control.

It is preferable that the assist wiring is one common wiring extending across a plurality of storage areas that is consecutive in a row or column direction, and that the individual second switch of the consecutive individual storage area can be turned on simultaneously.

Turning on the first switch, a current flows into the assist wiring across the plurality of storage areas, and therefore, if the second switch is turned on simultaneously at this time, the magnetization direction of these storage areas can be changed simultaneously.

Moreover, it is preferable that the individual storage area includes a second fixed layer via an insulating layer at the opposite side of the fixed layer of the magnetosensitive layer, and that the magnetosensitive layer, insulating layer, and second fixed layer constitute a TMR (Tunnel Magnetoresistance) element. Since electrons that passed through the spin filter are introduced to the TMR element, writing and reading of information can be carried out.

Moreover, the magnitude of the magnetic field reversal assist current supplied to the assist wiring is preferably set so that the external magnetic field strength that generates in the individual magnetosensitive layer may be more than or equal to the anisotropic magnetic field strength of the magnetosensitive layer.

### ADVANTAGE OF THE INVENTION

According to the magnetic memory and spin injection method of the present invention, the magnetization direction of the magnetosensitive layer can be changed by flowing a small current by simple control.

### BRIEF DESCRIPTION OF THE DRAWINGS

FIG. 1A is a vertical cross-sectional view of a magnetoresistance effect element (when magnetization directions are in parallel).

FIG. 1B is a vertical cross-sectional view of the magnetoresistance effect element (when magnetization directions are in antiparallel).

FIG. 2 is a view for illustrating the magnetization direction V_{β} in a magnetosensitive layer F1.

FIG. 3 is a timing chart of a magnetic field reversal assist current I_{AE} and write current I_{W}.

FIG. 4 is a timing chart at the time of rising of an improved magnetic field reversal assist current I_{AE}.

FIG. 5 is a graph showing an operation region of the current of a conventional magnetic memory.

FIG. 6 is a perspective view of a single storage area constituting a magnetic memory.

FIG. 7 is a perspective view in the vicinity of the magnetoresistance effect element.

FIG. 8 is a vertical cross-sectional view of a switch (N-type field-effect transistor) Q shown in FIG. 6.

FIG. 9 is a perspective view of a magnetic memory including a plurality of storage areas (cells) CEL.

### DESCRIPTION OF THE PREFERRED EMBODIMENTS

Hereinafter, a magnetic memory and a spin injection method concerning an embodiment will be described. The same numerals are used for the same elements and the duplicating description is omitted. The magnetic memory concerning the embodiment includes a plurality of storage areas, and each storage area has a magnetoresistance effect element.

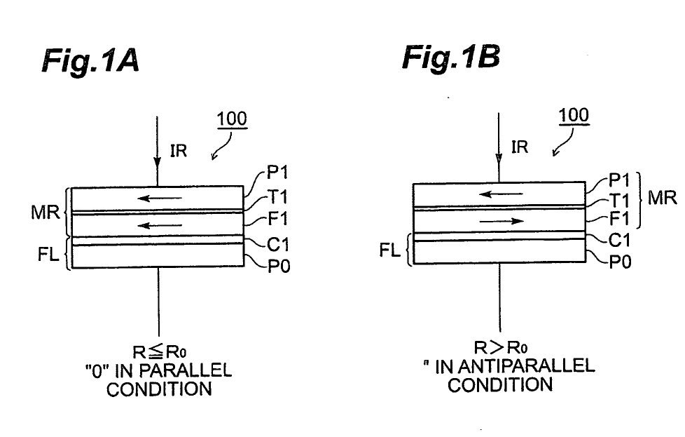

FIG. 1A is a vertical cross-sectional view of a magnetoresistance effect element 100 (when magnetization directions are in parallel). FIG. 1B is a vertical cross-sectional view of the magnetoresistance effect element 100 (when magnetization directions are in antiparallel).

The magnetoresistance effect element 100 is formed by sequentially laminating a fixed layer P0 made of ferromagnetic material, a non-magnetic layer C1, a magnetosensitive layer F1 made of ferromagnetic materials, an insulating layer T1 constituting a tunnel barrier layer, and a second fixed layer P1. The ferromagnetic fixed layer P0 and non-magnetic layer C1 constitute a spin filter FL. Moreover, the magnetosensitive layer F1, insulating layer T1, and second fixed layer P1 constitute a TMR element MR.

Since electrons that passed through the spin filter are introduced to the TMR element MR, writing and reading of information can be carried out depending on whether the magnetization direction of the magnetosensitive layer F1 and the magnetization direction of the second fixed layer P1 are in parallel or antiparallel.

“1” and “0” of memory information are defined depending on the state of the magnetization directions of the second fixed layer P1 and magnetosensitive layer F1 that constitute the TMR element MR, namely depending on whether the magnetization directions are in parallel (FIG. 1A) or antiparallel (FIG. 1B). When the magnetization directions of the second fixed layer P1 and magnetosensitive layer F1 are antiparallel (FIG. 1B), the value of electric resistance in the thickness direction is high as compared with when the magnetization directions are in parallel (FIG. 1A). In other words, a resistance R at the time of parallel is less than or equal to a threshold R₀, and the resistance R at the time of antiparallel becomes higher than the threshold R₀. Accordingly, the reading of information of “1” and “0” is carried out by flowing a current IR in the thickness direction of the TMR element MR and measuring the resistance value or current value of the TMR element due to MR (magnetoresistance) effect.

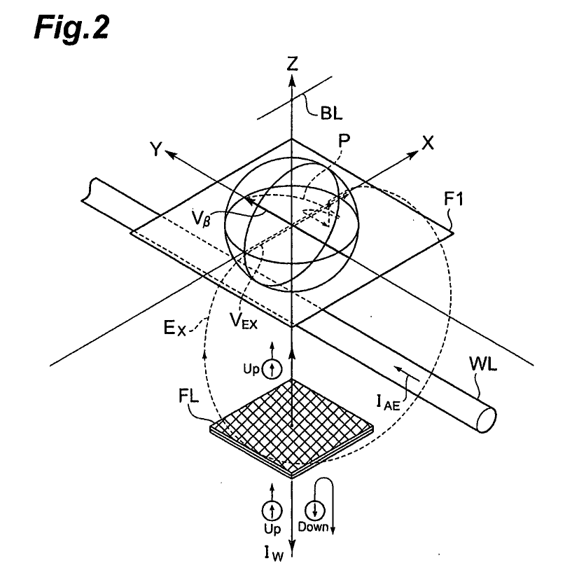

FIG. 2 is a view for illustrating a magnetization direction V_{β} in the magnetosensitive layer F1.

The writing of information of “1” and “0” to this magnetoresistance effect element 100 is carried out by rotating the magnetization direction of the magnetosensitive layer F1 by an external magnetic field E_{X} that is formed by flowing a current (magnetic field reversal assist current) I_{AE} into a word line (assist wiring) WL disposed in the vicinity of the magnetoresistance effect element 100, and by a spin transfer torque that acts on the magnetization direction V by spin injection (write current I_{W}) to the magnetosensitive layer F1 via a bit line BL. The external magnetic field E_{X} is generated by flowing a current into the word line WL provided in the vicinity of the magnetosensitive layer F1.

The magnetization direction V_{β} of the magnetosensitive layer F1 agrees with the magnetization easy axis (Y-axis), and the magnetization difficult axis is perpendicular to the magnetization easy axis (X-axis) in the XY plane.

First, upon energizing the magnetization reversal assist current I_{AE} into the word line WL, the external magnetic field E_{X} is generated in the direction surrounding the longitudinal direction of the word line WL, thus providing the external magnetic field E_{X} in the magnetosensitive layer F1. If the current I_{AE} is flowed to +Y direction, a magnetic field clockwise along a traveling direction is generated, thus directing the external magnetic field E_{X} to +X direction in the magnetosensitive layer F1. Namely, in the first step, the external magnetic field E_{X} having a direction component perpendicular to the magnetization easy axis Y of the magnetosensitive layer F1 is generated in the plane of the magnetosensitive layer MR.

The magnetosensitive layer F1 has a high aspect ratio in the Y direction, and the direction of the anisotropic magnetic field thereof agrees with the Y axis. Given the external magnetic field E_{X}, the magnetization direction V_{β} starts to rotate about the Z-axis along the dotted line P. Namely, in the first step, the magnetization direction V_{β} of the magnetosensitive layer F1 rotates toward the direction (magnetization difficult axis direction X) perpendicular to the magnetization easy axis (Y) with the assist of the external magnetic field E_{X}.

The magnitude of the external magnetic field E_{X} applied in the magnetization difficult axis direction of the magnetosensitive layer F1 is set larger than that of the anisotropic magnetic field (Y axis direction) of the magnetosensitive layer F1. In this case, the initial magnetization direction V_{β} along the magnetization easy axis Y rotates in the direction of the external magnetic field E_{X}.

The spin filter FL allows the electrons with a spin of a specific direction to transmit or reflects them. Here, it is assumed that electrons with an up-spin have transmitted the spin filter. In the second step, electrons with a spin that is polarized in the direction having a component perpendicular to the film plane are injected in the magnetosensitive layer F1. Injecting the polarized spin in the magnetosensitive layer F1, the spin transfer torque will also act on a vector that defines the magnetization direction V_{β} and the vector will rotate in the polarization direction of the polarized spin. Continuously applying the external magnetic field E_{X} to the magnetosensitive layer F1 while applying the spin transfer torque, the vector with the magnetization direction V_{β} in the magnetosensitive layer F1 will precess.

In the third step, the magnetic field strength generated in the first step is reduced during the execution period of the second step, preferably reduced to zero, and the magnetization direction V_{β} of the magnetosensitive layer F1 is inclined to the magnetization easy axis direction from the magnetization difficult axis (+X direction), so that the effective magnetic field direction of the magnetosensitive layer is changed to the magnetization easy axis direction. In addition, if the direction of the write current I_{W} is reversed, a spin with the direction opposite to the above will be reflected by the spin filter FL, and a spin transfer torque with the opposite direction will act on the vector that defines the magnetization direction V_{β}, and thus the vector will rotate in the polarization direction of the polarized spin.

According to this spin injection method, since the spin transfer torque acts while being assisted by the external magnetic field E_{X} that faces +X direction in the magnetosensitive layer F1, the magnetization direction V_{β} can be changed with a small current, and since the magnetization direction V_{β} can be controlled by just reducing the magnetic field strength so as to suppress an aberrance of magnetization direction V_{ρ} due to precession, the magnetic field being generated in the first step, a precise control of current value is not required. Accordingly, the magnetization direction V_{β} of the magnetosensitive layer F1 can be changed to the magnetization difficult axis direction (X axis) by flowing a small current by simple control.

The change of the magnetization direction from the magnetization difficult axis X to the opposite direction of the magnetization easy axis Y is easy, and an external magnetic field along the opposite direction of the magnetization easy axis Y just needs to be generated. Namely, the direction of the write current I_{W} just needs to be the same direction while the magnetization direction V is being fixed to the magnetization difficult axis X. The circuit design can be simplified because the write current I_{W} may not be flown in the opposite direction.

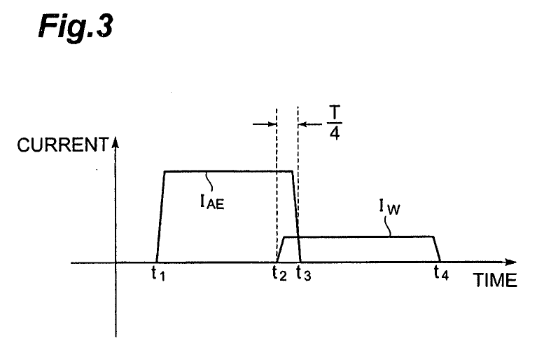

FIG. 3 is the timing chart of the above-described magnetic field reversal assist current I_{AE} and write current I_{W}.

In order to generate the external magnetic field E_{X}, at time t₁ the magnetic field reversal assist current I_{AE} starts to rise, thus executing the first step. In the second step, at time t₂ during execution of the first step, the write current I_{W} starts to flow into the magnetosensitive layer F1, and at time 4 after time t₃ when the magnetic field reversal assist current I_{AE} decreases to zero to finish the generation of the external magnetic field E_{X}, the supply of the write current I_{W} is stopped.

The overlap period (time t₂ to time t₃) between the execution period of the first step and the execution period of the second step is approximately ¼ (25±10%) of the ferromagnetic resonance period T of the magnetosensitive layer F1 (Δt=t₃−t₂=T/4). Note that ±10% is an error. Since the ferromagnetic resonance period T of the magnetosensitive layer F1 during which the spin transfer torque acts effectively is approximately 100 to 250 pico seconds, the overlap period Δt is 25 to 62.5 pico seconds. In the case where the overlap period Δt is approximately ¼ of the ferromagnetic resonance period T, the deflection angle from the magnetization difficult axis becomes the maximum, so that erroneous writing is unlikely to occur.

In addition, the maintaining time of the magnetic field reversal assist current I_{AE} is more than or equal to the time required to direct the magnetization to the difficult axis direction and is defined by Gilbert attenuation coefficient and is usually on the order of 10 ns.

In order to direct the magnetization direction V_{β} to the direction of the magnetization difficult axis (X) at high speed, a method of devising the rising method of the magnetic field reversal assist current I_{AE} can be considered.

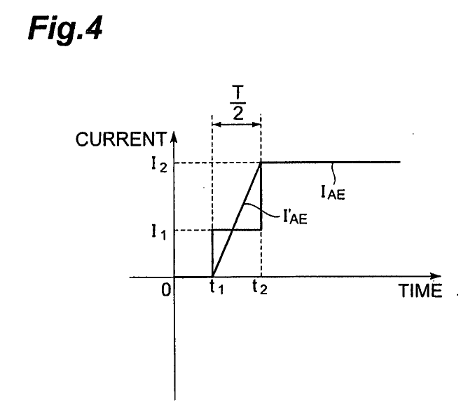

FIG. 4 is the timing chart at the time of the rising of the improved magnetic field reversal assist current I_{AE}. Incidentally, FIG. 2 will be referred to suitably in this description.

The external magnetic field E_{X} is generated by the magnetic field reversal assist current I_{AE}, so that the direction of a combined effective magnetic field of the external magnetic field E_{X} and the anisotropic magnetic field of the magnetosensitive layer F1 is approximately 45 degree direction (rotation angle from +Y axis toward +X axis). In this case, the magnetization direction V_{β} starts to precess according to LLG equation, and there is an instant that the magnetization direction V_{β} approaches the magnetization difficult axis X. If the magnetic field reversal assist current I_{AE} is increased at this instant so that the combined effective magnetic field completely turns to the magnetization difficult axis X, the magnetization direction V_{β} will stay in the direction of the magnetization difficult axis X.

That is, after setting the magnetic field reversal assist current I_{AE} to I₁ from time t₁ to time tₓ, the magnetic field reversal assist current I_{AE} is increased to I₂ at time tₓ. Note that, the rising time period of the external magnetic field E_{X} in the first step is 25±10% of the ferromagnetic resonance period T of the magnetosensitive layer F1. Incidentally, +10% is an error. If the rising time period is approximately ¼ (=25±10%) of the ferromagnetic resonance period T, an instant that the magnetization direction V_{β} of the magnetosensitive layer F1 during precession agrees with the magnetization difficult axis X will occur, and therefore, at this time if the external magnetic field E_{X} is strengthened so that the rising of the external magnetic field E_{X} may complete, the magnetization direction V_{β} will stay along the magnetization difficult axis X.

In addition, there is also a method of continuously increasing the magnetic field reversal assist current (shown as I_{AE}′), instead of two steps, and also in this case the magnetization direction V_{β} performs the same movement. In these methods, the magnetization direction V_{β} can be directed to the magnetization difficult axis direction (X) in 1 ns or less. In case of continuously changing the magnetic field reversal assist current, provision is made such that the combined effective magnetic field turns to the direction of approximately 45 degrees in approximately ⅛ of the ferromagnetic resonance period T after starting to flow the magnetic field reversal assist current, and further after approximately ⅛ of the ferromagnetic resonance period T the combined effective magnetic field turns to the difficult axis direction. Incidentally, approximately ¼ means 25±10%. Since the ferromagnetic resonance period T of the magnetosensitive layer F1 during which the spin transfer torque acts effectively is approximately 100 to 250 pico seconds, this rising time period (tₓ to t₁) is 40 to 60 pico seconds.

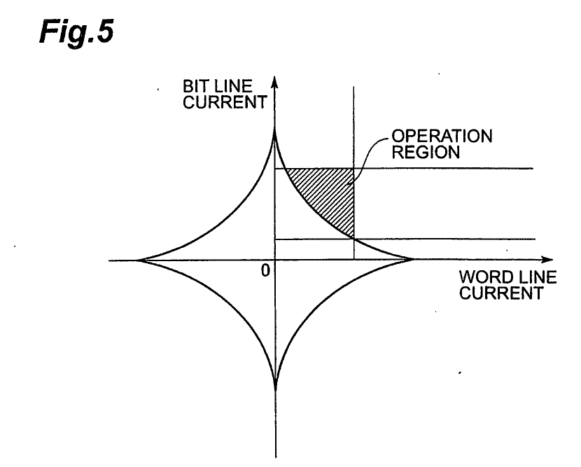

FIG. 5 is a graph showing the operation region of the current of a conventional magnetic memory. Since both word line current and bit line current usually apply the magnetic field also to an unselected storage area (cell), they may provide a disturbance to the unselected storage area to cause a malfunction. For this reason, the word line current and bit line current have an upper limit and a lower limit, thus limiting the operation region. The variation in the characteristic of the storage area causes fluctuation of the operation region, and therefore, taking this into consideration, it is difficult to guarantee the operation of the whole storage areas and is difficult to ensure a high bit yield.

On the other hand, according to the above-described method the amount of the write current I_{w} will not affect the unselected cell and therefore erroneous writing can be eliminated.

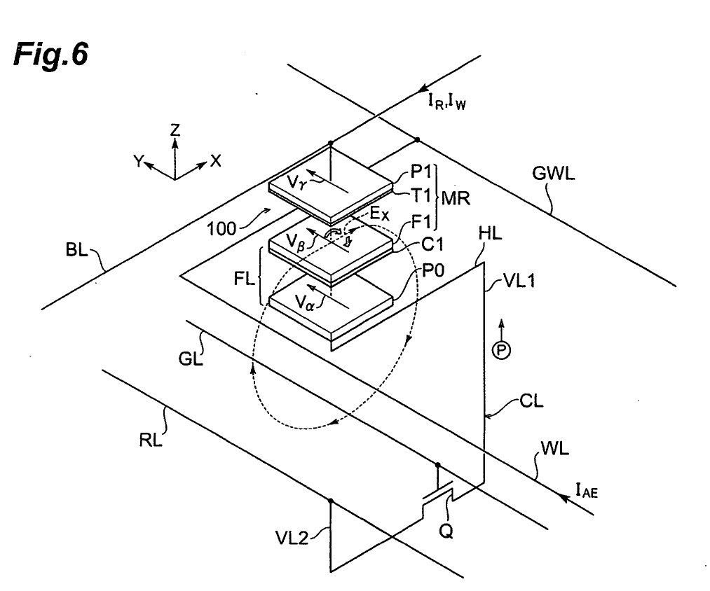

FIG. 6 is a perspective view of a single storage area constituting the magnetic memory.

This storage area includes a fixed layer P0 made of ferromagnetic material, a magnetosensitive layer F1 having a magnetization easy axis (Y) along the in-plane direction, the magnetosensitive layer facing the fixed layer P0 via a non-magnetic layer C1, a word line (assist wiring) WL for providing a magnetic field reversal assist magnetic field E_{X} in the magnetosensitive layer F1, and spin injection wirings BL, CL, and RL connected to the fixed layer P0.

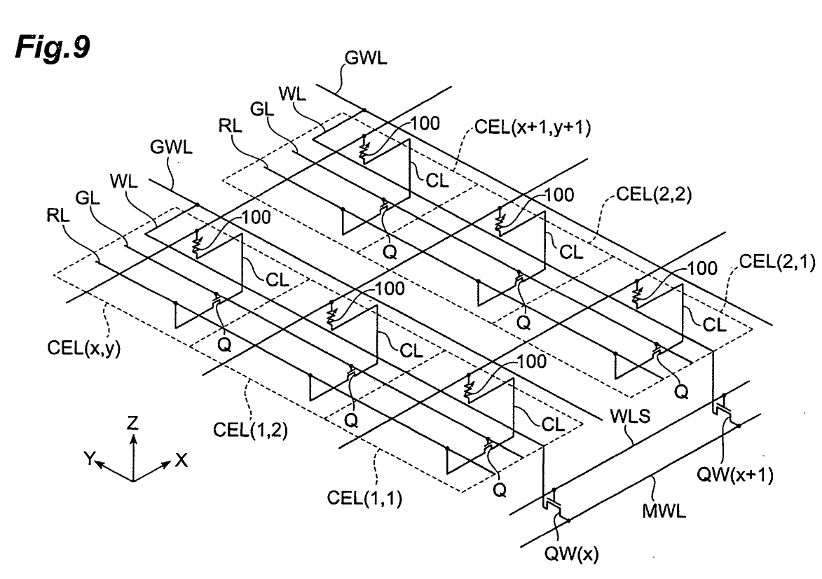

This storage area further includes a first switch (QW(X): see FIG. 9) that turns on so as to supply a magnetic field reversal assist current I_{AE} to the word line WL and thus generates in the plane of the magnetosensitive layer F1 the external magnetic field E_{X} having a direction component perpendicular to a magnetization easy axis Y of the magnetosensitive layer F1, and a second switch Q that turns on so as to supply electrons to the spin injection wirings BL, CL, and RL after turning on the first switch.

Turning on the first switch (QW(X): see FIG. 9), the first step of the above-described spin injection method is carried out, and then turning on the second switch, the second step is carried out and the first switch is turned off while the second switch Q is ON so that the third step may be carried out.

Accordingly, according to this magnetic memory, since the spin transfer torque acts on the magnetosensitive layer F1 while being assisted by the external magnetic field like in the above-described spin injection method, the magnetization direction can be changed with a small current, and since the magnetization direction V_{β} can be controlled by just reducing the magnetic field strength generated in the first step so as to suppress an aberration of magnetization direction due to precession, a precise control of current value is not required. Accordingly, the magnetization direction V, of the magnetosensitive layer F1 can be changed by flowing a small current by simple control.

At the opposite side of the fixed layer P0 of the magnetosensitive layer F1, a second fixed layer P1 is provided via an insulating layer T1, and the magnetosensitive layer F1, insulating layer T1, and second fixed layer P1 constitute a TMR element MR. Since electrons that transmitted a spin filter FL are introduced to the TMR element MR, writing and reading of information can be performed depending on whether a magnetization direction V_{Y} of the magnetosensitive layer F1 and the magnetization direction V of the second fixed layer P1 are in parallel or anti-parallel. The magnetization direction V_{Y} of the second fixed layer P1 is in +Y directions. Moreover, a magnetization direction V_{α} of the fixed layer P0 is perpendicular to the film plane.

As shown in FIG. 3, a first switch (QW(X): see FIG. 9) that supplies a magnetic field reversal assist current I_{AE} is turned off while a second switch Q that supplies a write current I_{W} is ON. The magnetic field reversal assist current I_{AE} flows through the word line WL that branches from a global word line GWL. A polarized spin due to the write current I_{W} is generated by the spin filter FL having the fixed layer P0 made of ferromagnetic material and the non-magnetic layer C1, and this polarized spin is injected in the magnetosensitive layer F1.

If the second switch (field-effect transistor) Q controlled by the potential of a gate line GL is turned on to flow the write current I_{W} of one direction from the bit line BL into the TMR element MR, then electrons flow from a return line RL to the spin filter FL via a vertical wiring VL2, the second switch Q, a vertical wiring VL1, and a horizontal wiring HL, thus injecting a polarized spin in the magnetosensitive layer F1.

If the second switch (field-effect transistor) Q controlled by the potential of the gate line GL is turned on to flow the write current I_{W} of the opposite direction from the bit line BL to the TMR element MR, then the polarized spin of the opposite direction is injected in the magnetosensitive layer F1, and this write current I_{W} flows into the return line RL via the horizontal wiring HL, vertical wiring VL1, and the second switch Q. Although the direction of the write current I_{W} can be changed by changing the potentials of the bit line BL and return line RL, a voltage required for turning on the gate of an nMOS switch will be increased. However, if a method is employed in which at the time of writing in the opposite direction the direction of the write current is made the same and the assist magnetic field is reversed, such adverse effect will not occur.

Although the operation at the time of reading information is the same as at the time of writing, a read current Ir may be of a small current value or of the same order unlike the write current I_{W} that flows through the bit line.

In addition, although the TMR element MR is energized at the time of both reading and writing, if the external magnetic field is not applied at the time of reading, then the magnetization will not be reversed, and therefore, there is also a benefit that the magnetization stability at the time of reading can be secured without reducing the applied voltage to the TMR element MR at the time of reading. Note that, in the case of the conventional writing by means of a spin transfer torque, in consideration of not causing a magnetization reversal at the time of reading, the voltage or current at the time of reading is made sufficiently small as compared with at the time of writing, so that a difficulty in reading or a decrease in the read speed will occur. Moreover, if Gilbert attenuation coefficient of the magnetosensitive layer F1 is increased, the stability at the time of reading can be increased further.

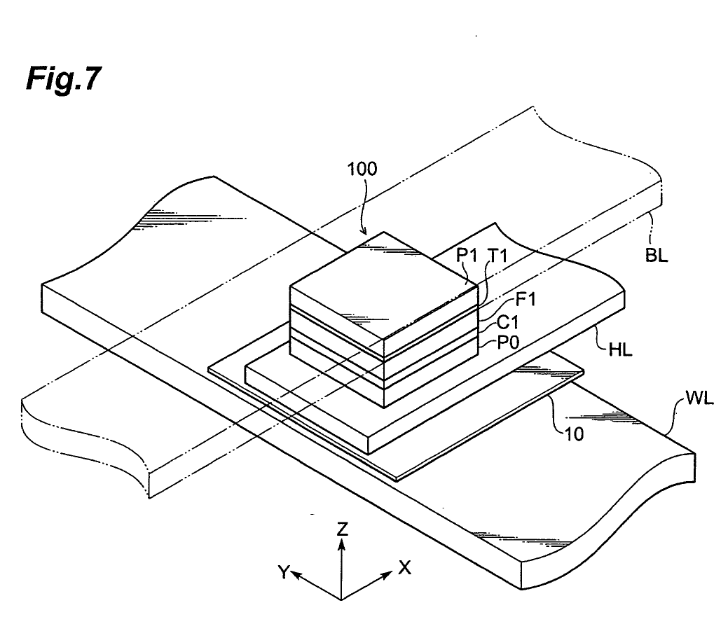

FIG. 7 is a perspective view in the vicinity of the magnetoresistance effect element.

The horizontal wiring HL is provided via an insulating layer 10 on the word line extending in the Y axis direction, and this horizontal wiring HL extends along the Y axis direction. The horizontal wiring HL is in contact with the fixed layer P0, and the second fixed layer P1 is in contact with the bit line BL extending along the X axis direction.

Incidentally, as the material of the magnetosensitive layer F1, ferromagnetic material, such as Co, CoFe, NiFe, NiFeCo, CoPt, and CoFeB, can be used, for example.

As the material of the non-magnetic insulating layer T1 constituting the TMR element MR, the oxide or nitride of metal (e.g., Al, Zn, Mg, or the like), e.g., Al₂O₃ and MgO, are suitable. As the structure of the fixed layer P0 and the second fixed layer P1, an exchange coupling type of applying an antiferromagnetic layer to a ferromagnetic material layer can be used. Moreover, as the material of antiferromagnetic material, IrMn, PtMn, FeMn, NiMn, PtPdMn, RuMn, NiO, or a material of combination of any of these can be used. As the material of the non-magnetic layer C1, Cu or Ru can be used.

As various kinds of wiring materials, Cu, AuCu, W, Al, or the like can be used.

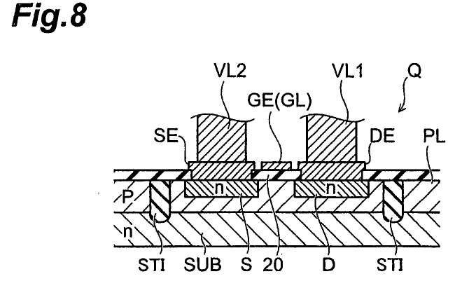

FIG. 8 is the vertical cross-sectional view of the switch (N-type field-effect transistor) Q shown in FIG. 6.

A p-type semiconductor layer PL is formed on an n-type substrate SUB, and the p-type semiconductor layer PL is isolated by an isolation region (shallow trench isolation) STI. In the p-type semiconductor layer PL inside the isolation region STI, there are formed an n-type source region S and a drain region D, on top of which a source electrode SE (vertical wiring VL2) and a drain electrode DE (vertical wiring VL1) are formed, respectively. An insulating layer 20 is provided in the substrate surface, and a gate electrode GE (gate wiring GL) is provided on the insulating layer 20 above between the source region S and drain region D.

FIG. 9 is a perspective view of a magnetic memory including a plurality of storage areas (cells) CEL.

The storage areas CEL are arranged in a matrix in the XY plane, and the structure of each storage area CEL (x, y) is as shown in FIG. 6. Here, the word line WL (assist wiring) shown in FIG. 6 is one common wiring extending across a plurality of storage areas CEL (1, 1), CEL (1, 2), . . . , and CEL (x, y) that are consecutive in the column direction (may be in the row direction), and the individual second switch Q of the consecutive individual storage area CEL (1, 1), CEL (1, 2), . . . , or CEL (x, y) can be turned on simultaneously. Turning on the first switch QW(x), a current I_{AE} flows into the word line WL across a plurality of storage areas CEL (1, 1), CEL (1, 2), . . . , and CEL (x, y) in the column direction. Therefore, if the second switch Q is turned on simultaneously at this time, magnetization directions of these storage areas CEL (1, 1), CEL (1, 2), . . . , and CEL (x, y) can be changed simultaneously.

Moreover, turning on a first switch QW (x+1) corresponding to a row adjacent to the above-described row, the current I_{AE} flows into the word line WL across a plurality of storage areas CEL (2, 1), CEL (2, 2), . . . , and CEL (x+1, y+1) in the column direction. Therefore, if the second switch Q is turned on simultaneously at this time, magnetization directions of these storage areas CEL (2, 1), CEL (2, 2), . . . and CEL (x+1, y+1) can be changed simultaneously. Incidentally, the number of storage areas on one word line WL is a number of being writable at one time and is usually set to 8, 16, 32, 64, or the like.

As described above, at the time of writing in this magnetic memory, a plurality of word lines WL connected to a global word line GWL is energized, and then, depending on an information to be written in between the bit line BL and return line RL, a positive or negative potential difference is applied and the potential of the gate line (gate electrode) GL is made positive, thereby putting the switch Q in a conducting condition to supply current to the magnetoresistance effect element 100. That is, a bi-directional current is supplied to the magnetosensitive layer F1 by a method of increasing or decreasing the potential of the bit line BL with respect to the return line RL.

In addition, as described above, a current is flown into the magnetoresistance effect element 100, and after ¼ of the ferromagnetic resonance period T of the magnetosensitive layer F1, the current I_{AE} of the word line WL is disconnected. The current I_{AE} flowing through the word line WL is controlled by controlling the potential of a word line selection line MWL. Although the first switches (field-effect transistors) QW(x) and QW (x+1) are interposed between the word line selection line MWL and the word line WL, both these gate electrodes are connected to one common selection gate line WLS. Accordingly, increasing the potential of the common selection gate line WLS, the potential of the word line WL of each row can be increased simultaneously, thus enabling execution of high-speed writing.

At the time of reading, by applying a positive voltage to the gate line (gate electrode) GL, the transistor is put in a conducting condition to measure the current between the return line RL and the bit line BL, thereby reading the resistance of the magnetoresistance effect element 100.

In addition, as a method of realizing the control of each control line in a time difference of 1 ns or less, a method may be used in which the time difference is produced by using the same pulse signals and routing these through circuits with different delay times. Moreover, as a method of adjusting this delay time, a method of using a circuit that can adjust the delay time with an electrical method can be also used.

As described above, according to the above-described magnetic memory and spin injection method, the magnetization direction of the magnetosensitive layer can be changed by flowing a small current by simple control. Note that, according to the above-described embodiment, the magnitude of the spin transfer torque may be smaller than that with other methods. That is, in this embodiment method, the magnitude of the spin transfer torque is ¼ of the relaxing switching method (when Gilbert attenuation coefficient is 0.01 and the in-plane anisotropy magnetic field is 100 Oe), ½ of the precessional switching method, and is comparable to the relaxing-precessional switching method.

Moreover, according to the above-described embodiment, since the spin transfer torque can be controlled by a switch transistor for each cell, there is an advantage that an erroneous writing to an unselected cell will not occur. Moreover, according to the above-described embodiment method, there is also an advantage that the current value that produces a spin transfer torque required for writing can be made a half or less as compared with a method not using the external magnetic field.

What is claimed is:

1. A spin injection method of injecting electrons for changing a magnetization direction of a magnetosensitive layer, the method comprising:
a first step of generating in a plane of the magnetosensitive layer an external magnetic field having a direction component perpendicular to a magnetization easy axis of the magnetosensitive layer;
a second step of injecting in the magnetosensitive layer electrons having a spin polarized in a direction having a component perpendicular to a film plane; and
a third step of reducing a magnetic field strength generated in the first step during execution of the second step.

2. The spin injection method according to claim 1, wherein a magnitude of the external magnetic field applied in a magnetization difficult axis direction of the magnetosensitive layer in the first step is set larger than that of an anisotropic magnetic field of the magnetosensitive layer.

3. The spin injection method according to claim 1, wherein an overlap period between an execution period of the first step and an execution period of the second step is 25±10% of a ferromagnetic resonance period of the magnetosensitive layer.

4. The spin injection method according to claim 3, wherein the overlap period is 25 to 62.5 pico seconds.

5. The spin injection method according to claim 1, wherein a rising time period of the external magnetic field in the first step is 25±10% of the ferromagnetic resonance period of the magnetosensitive layer.

6. The spin injection method according to claim 5, wherein the rising time period is 40 to 60 pico seconds.

7. The spin injection method according to claim 1, wherein the external magnetic field is generated by flowing a current into an assist wiring that is provided in the vicinity of the magnetosensitive layer.

8. A magnetic memory comprising a plurality of storage areas,
the individual storage area including:
a fixed layer made of ferromagnetic material;
a magnetosensitive layer having a magnetization easy axis along an in-plane direction, the magnetosensitive layer facing the fixed layer via a non-magnetic layer;
an assist wiring for providing a magnetic field reversal assist magnetic field in the magnetosensitive layer; and
a spin injection wiring connected to the fixed layer,
the magnetic memory further comprising:
a first switch that turns on so as to supply a magnetic field reversal assist current to the assist wiring and to thus generate in the plane of the magnetosensitive layer an external magnetic field having a direction component perpendicular to a magnetization easy axis of the magnetosensitive layer; and
a second switch that turns on so as to supply electrons to the spin injection wiring after turning on the first switch, wherein
the first switch is turned off while the second switch is ON, and wherein
a magnetization direction of the fixed layer is perpendicular to a film plane.

9. The magnetic memory according to claim 8, wherein the assist wiring is one common wiring extending across the plurality of storage areas that is consecutive in a row or a column direction, and wherein the individual second switch of the consecutive individual storage area can be turned on simultaneously.

10. The magnetic memory according to claim 9, wherein
the individual storage area includes a second fixed layer via an insulating layer at an opposite side of the fixed layer of the magnetosensitive layer, and wherein
the magnetosensitive layer, the insulating layer, and the second fixed layer constitute a TMR element.

11. The magnetic memory according to claim 8, wherein a magnitude of the magnetic field reversal assist current supplied to the assist wiring is set so that an external magnetic field strength generated in the individual magnetosensitive layer may be more than or equal to an anisotropic magnetic field strength of the magnetosensitive layer.
